(19) United States
(12) Patent Application Publication
(10) Pub. No.: US 2004/0115939 A1
(43) Pub. Date: Jun. 17, 2004

(54) Sterilization method

(76) Inventor: John Field, Bath (GB)

Correspondence Address: STAAS & HALSEY LLP, SUITE 700, 1201 NEW YORK AVENUE, N.W., WASHINGTON, DC, 20005, US

(21) Appl. No.: 10/475,304

(22) PCT Filed: Apr. 25, 2002
(86) PCT No.: PCT/GB02/01907

(30) Foreign Application Priority Data
Apr. 25, 2001 (GB) 0110191.4

(51) Int. Cl. H01L 21/302; H01L 21/461

(52) U.S. Cl. 438/689

(57) ABSTRACT

A method is provided of sterilizing an object carrying an organic material. The method comprises exposing the object to a plasma of ionised gas whereby the organic material on the object reacts with the plasma to generate one or more volatile products which are then removed.

The invention relates to a method of sterilizing an object contaminated with organic material.

Conventionally, medical instruments and the like need to be carefully sterilized before use in medical procedures. There are many techniques for achieving sterilization such as heating to a high temperature, or the use of antimicrobial agent such as hydrogen peroxide or ethylene oxide, and the like. Recently, with the growth in concern about the transfer of CJD and similar diseases by organic contamination such as prions, conventional sterilization techniques have been considered unsafe and disposable instruments have been developed for certain medical procedures, which are destroyed after use. Although this is an acceptable approach, problems arise with certain instruments which are often complex and too expensive to throw away after a single use.

In accordance with the present invention, a method of sterilizing an object carrying organic material comprises exposing the object to a plasma of ionised gas and simultaneously exposing a monitoring object to the same plasma, the monitoring object comprising a substrate carrying a substance,

whereby the organic material on the object and the substance on the substrate each react with the plasma to generate one or more volatile products such that the reaction causes a visible change in the monitoring object by the removal of the substance from the substrate;

removing the product(s); and

monitoring the monitoring object to determine whether exposure to the plasma has occurred.

We have realized that the use of a plasma to achieve sterilization may overcome the problems outlined above. The use of plasmas is well known in the area of semiconductor fabrication. We have realized that many processes are based on organic compounds and thus surprisingly this use of a plasma could be adapted for sterilization. In the context of the present invention, the term “sterilization” is intended to mean a process to effect a clean (“sterile”) environment by the destruction and/or removal of organic material in any form. In particular, the organic material is intended to include “non-living” entities such as prions.

An important application of the invention is therefore where the organic material comprises prions but it could also be used with other organic material such as “living” material, as with other sterilization techniques.

The plasma typically comprises ionized oxygen but other gases such as the Fluorine based gases, for example carbon tetrafluoride, could be used or added. Other examples of fluorine based gases are CHF₃ and C₂F₆. Other gases commonly used for the etching of organic materials are: CH₄, BCl₃, Ar and N₂.

Occasionally, it is has been found in the semiconductor industry that the equipment fails to generate a plasma and the operator is unaware of this when he unloads the object and passes it on to the next manufacturing stage. This has been widely recognized in the semiconductor industry and methods and checks have been developed to deal with it. These typically involve the use of extra instruments to check that the plasma has been ignited. For example, a photodetector is often used to detect the light from the discharge. However, if a multiple failure is considered then it is possible to imagine a set of circumstances whereby the machine still appears to have operated successfully but in fact has not. Although the probability of this is so low as to be acceptable in the semiconductor industry, it would not be acceptable in sterilization procedures.

Preferably, the method further comprises simultaneously exposing a monitoring object to the same plasma, the monitoring object comprising a substrate carrying a substance which reacts with the plasma to undergo a visible change.

In this way, the operator can-check the monitoring object to see whether it has reacted with the plasma and if it has, this will confirm that the plasma has been generated and thus the object has been sterilized.

Typically, the substance reacts with the plasma to generate one or more volatile products and so may comprise a photoresist or the like. Conveniently the substance is opaque, the substrate carrying indicia covered by the substance and which are revealed following reaction of the substance with the plasma.

Any conventional plasma generating apparatus could be used to implement the method, a particularly suitable apparatus being a Barrel Reactor.

An example of apparatus for carrying out a method according to the present invention will now be described with reference to the accompanying drawings, in which:—

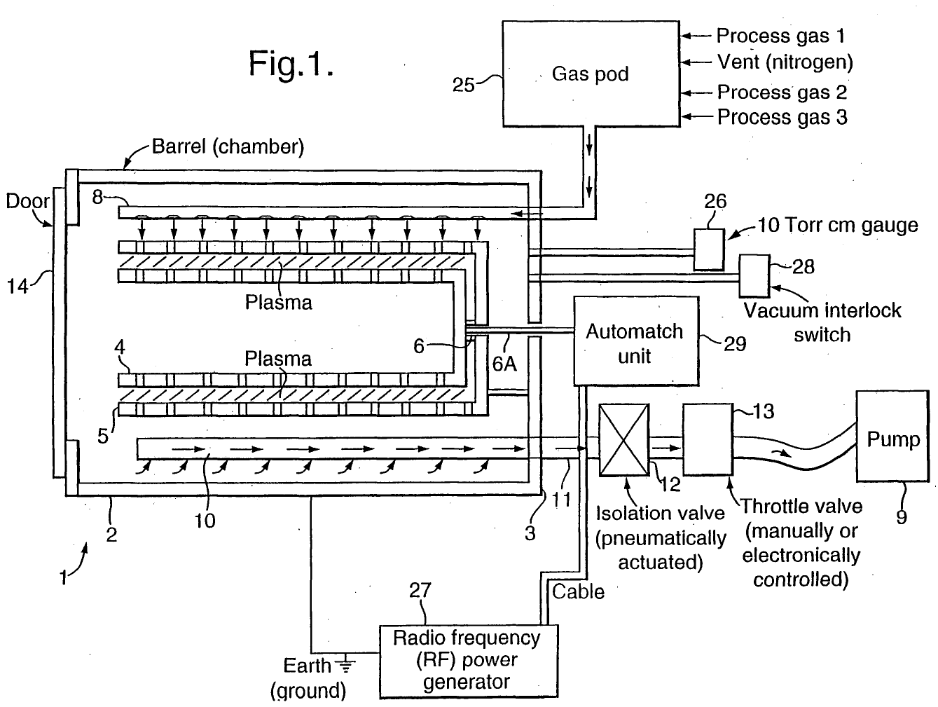

FIG. 1 is a schematic block diagram of the apparatus;

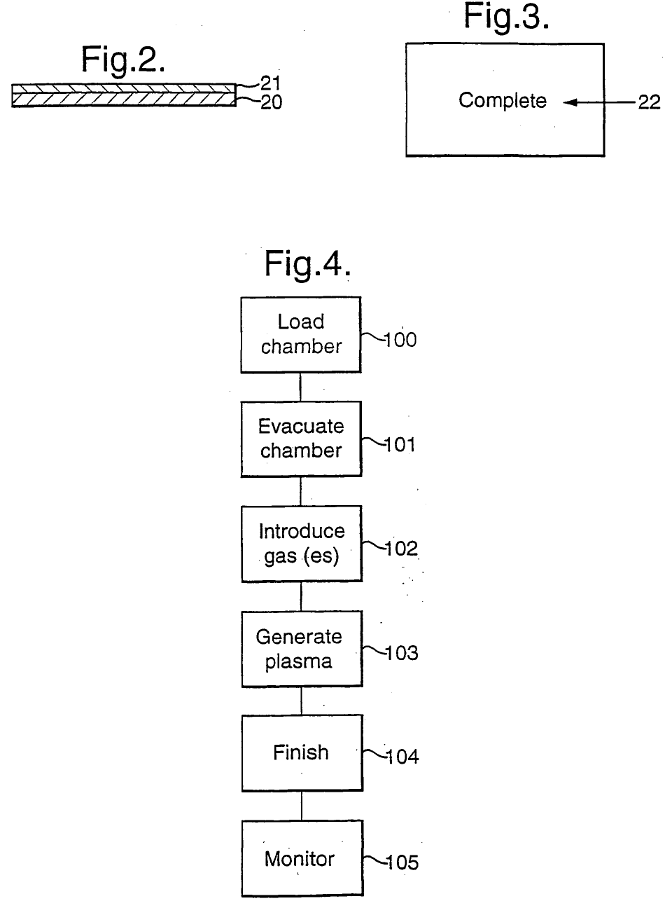

FIG. 2 is a cross-section through a monitoring object;

FIG. 3 is a plan of the monitoring object shown in FIG. 2 with the photoresist layer removed; and,

FIG. 4 is a flow diagram of an example method using the apparatus.

The drawing illustrates a barrel reactor sold by Oxford Instruments Plasma Technology Limited under the name Plasmalab™. The reactor comprises a barrel chamber 1 consisting of a horizontal aluminium cylinder 2 with a bolted or welded back-plate 3.

A pair of electrodes 4,5 consisting of two aluminium cages are provided, one inside the other. The outer electrode 5 is bolted to the barrel 2, and the inner 4 is secured to the outer 5, but they are insulated from one another by means of ceramic spacers 6. A feed-through 6A carries RF power input.

The gas inlet to the barrel chamber 1 is via a tube 8 which runs parallel with the top of the chamber and above the outer electrode 5.

A pump 9 is connected to a large diameter tube 10 running along parallel with the chamber beneath the outer cage 5, leaving the chamber via a large diameter extension tube 1. This tube is O-ring sealed to the back-plate 3 and terminates in a high vacuum valve 12 which is connected to the pump 9 via a throttle valve 13.

The chamber has a front door 14 containing a Pyrex glass viewport and seals into an O-ring surrounding the door aperture by means of adjustable spring hinges (not shown), which allow a parallel closing action.

Referring to FIG. 4, in operation at step 100, an instrument to be sterilized is placed in the chamber 2 supported by the inner cage 4. In addition, a monitoring object is positioned in the chamber.

An example of a monitoring object is shown in FIGS. 2 and 3. The object comprises a base 20 on which has been deposited a photoresist 21. The base 20 carries a printed message which can be seen in FIG. 3 at 22. This message is obscured initially by the photoresist 21.

The chamber door 14 is then closed and the isolation valve 12 between the chamber and the pump (which normally runs continuously) is opened. The air is then pumped out of the chamber to create a very “high” vacuum at step 101.

The process gases are then introduced via a gas pod 25 into the chamber via two tubes 8 (only one shown) which run parallel to the top of the chamber (step 102). The gases are controlled by electrically operated valves and mass flow controllers (not shown). Typically the pressure is about 1 Torr, roughly one thousandth of an atmosphere and this is monitored by a gauge 26.

A Radio Frequency (RF) generator 27 is then switched on at step 103. This is connected to the electrodes 4,5 in the chamber via an Automatch unit 29.

A vacuum interlock switch 28 ensures that neither the RF nor the process gases are enabled before the chamber pressure is below a set level.

The processing pressure in the chamber is controlled either manually by the throttle valve 13 located between the pump 9 and the isolation valve 12, or by a fully automatic adaptive pressure controller which provides separate pressure and gas flow controls.

Typically, the pump 9 is of the rotary vane type. In these, an oil sealed eccentrically mounted vane traps the gas as it rotates and sweeps it to the outlet port.

The RF generator power transforms the gases into a plasma in the space between the two electrodes 4,5.

The impedance (a form of electrical resistance present in circuits having oscillating current) of the plasma varies from one process to another and also during a process. Since the RF generator 27 is designed to operate into a fixed load or impedance, an element whose impedance automatically adjusts to suit the varying plasma load must be used. The Automatch Unit 29, which is a motorised network of capacitors and inductors, performs this function.

In more detail, to create a plasma, energy is imparted to a stable gas to excite the free electrons causing collisions thereby creating ions and radicals. For example, an electron colliding with an oxygen molecule can produce radicals as follows:

e+O₂=>O+O+e

Or, rather then separating the stable O molecule, an electron may be dislodged yielding:

e+O₂=>O₂₊+2e

The process converts relatively unreactive gas molecules into very reactive radicals and ions.

A typical reaction using an oxygen based plasma in the context of etching an organic material such as polyethelene (CH₂)ₙ, has the form:

(CH₂)ₙ+2O=>CO+H₂O

Alternatively, with a fluorine based gas such as carbon tetrafluoride, a reaction of the following form will take place:

(CH₂)ₙ+6F=>CF₄+2HF

Both of these reactions result in the generation of volatile products, these can be pumped away and rendered harmless by conventional exhaust treatment methods.

During this process at step 103 when the plasma is present within the chamber 2, any organic material present upon the instrument in question, along with the photoresist layer upon the monitoring object, reacts with the plasma. Reactions of the kind mentioned above break down this organic material and generate the resultant volatile products which are then removed from the chamber as a result of the gas flow.

Any microorganisms within the chamber are therefore killed by the plasma. In addition and in contrast to known methods, the present invention also produces a sterile environment by breaking down and removing other organic materials such as prions. As prions are relatively simple organic structures rather than living organisms, they are consequently more difficult to render harmless. The break down of the organic material and its removal in the form of volatile products, cleans the objects within the chamber since the organic material is physically removed.

The present invention advantageously provides an environment in which the desired plasma conditions can be generated and maintained indefinitely. This allows organic materials to be subjected to a prolonged attack which is capable of destroying and removing even the most resistant prions.

During this process it is important to generate optimized plasma conditions for the destruction and removal of organic matter, since the behaviour of a plasma is strongly dependent upon such conditions. In fact, non-ideal conditions may serve to actually “bake” the organic material onto the object in question. The controlled introduction and removal of the gases from the chamber ensures that a constant and stable environment is produced which does not vary as a function of time. Such an environment is ideal for generating optimized plasma conditions. Typical processing times of the order of tens of minutes are often needed to ensure the complete removal of prion materials and these processing times can be achieved using the present method.

Although a gas flow is present during the process, uniformity of the gas composition within the chamber can be achieved by careful design.

Once the process of removing the organic material has been completed, the generation of the plasma is halted at step 104. The chamber is then returned to atmospheric pressure. At step 105, the monitoring object is examined either visually or with the aid of appropriate apparatus to determine whether the photoresist layer 21 has been removed and therefore whether the plasma process has been effective. It should also be noted that the monitoring step 105 could be performed in situ whilst the instrument and monitoring object are present within the chamber. This could be achieved by the use of the glass view port within the front door 14.

It is envisaged that the present method may be used in combination with or as a replacement for conventional sterilization methods.

1. A method of sterilizing an object carrying organic material, the method comprising:—
exposing the object to a plasma of ionised gas and simultaneously exposing a monitoring object (20) to the same plasma, the monitoring object comprising a substrate carrying a substance,
whereby the organic material on the object and the substance on the substrate each react with the plasma to generate one or more volatile products such that the reaction causes a visible change in the monitoring object by the removal of the substance from the substrate;
removing the product(s); and
monitoring the monitoring object to determine whether exposure to the plasma has occurred.

2. A method according to claim 1, wherein the organic material comprises prions.

3. A method according to claim 1 or claim 2, wherein the plasma is an oxygen or fluorine gas based plasma.

4. A method according to any of claims 1 to 3, wherein the substance comprises a photoresist (21).

5. A method according to any of claims 1 to 4, wherein the substance is opaque, the substrate carrying indicia covered by the substrate and which are revealed following reaction on of the substance with the plasma.

6. A method according to any of the preceding claims, wherein the plasma is generated within a chamber (2) and, during exposure of the object to the plasma, one or more gases are supplied to and removed from the chamber such that a substantially constant pressure is maintained within the chamber.

7. A method according to claim 6, wherein the gas(es) supplied to the chamber are process gas(es) from which the plasma is generated.

8. A method according to claim 6 or claim 7, wherein the gas removed from the chamber comprises the volatile products.

9. A method according to any of claims 6 to 8, wherein substantially constant plasma conditions are maintained within the chamber during exposure of the object.
